(19) United States
(12) Patent Application Publication
(10) Pub. No.: US 2012/0038045 A1
(43) Pub. Date: Feb. 16, 2012

(54) Stacked Semiconductor Device And Method Of Fabricating The Same

(75) Inventor: Ho-Cheol Lee, Yongin-si (KR)

(73) Assignee: SAMSUNG ELECTRONICS CO., LTD., Suwon-si (KR)

(21) Appl. No.: 13/110,433

(22) Filed: May 18, 2011

(30) Foreign Application Priority Data
Aug. 12, 2010 (KR) 10-2010-0077827

(51) Int. Cl. H01L 23/498; H01L 23/48; H01L 21/50

(52) U.S. Cl. 257/738; 257/737; 438/107; 257/774; 257/E23.069; 257/E23.068; 257/E21.499; 257/E23.011

(57) ABSTRACT

A stacked semiconductor device may have a plurality of chips stacked in three-dimension. The stacked semiconductor device may include a first semiconductor chip and at least one second semiconductor chip. The first semiconductor chip may include a plurality of first through silicon vias (TSVs). The at least one second semiconductor chip may include a plurality of second TSVs. The at least one second semiconductor chip may be stacked above the first semiconductor chip and may be thinner than the first semiconductor chip. Therefore, the stacked semiconductor device may have an improved reliability.

### CROSS-REFERENCE TO RELATED APPLICATION

This application claims priority under 35 U.S.C. §119 to Korean Patent Application No. 10-2010-0077827 filed on Aug. 12, 2010 in the Korean Intellectual Property Office (KIPO), the disclosure of which is hereby incorporated by reference in its entirety.

### BACKGROUND

1. Field

Example embodiments of the inventive concepts relate to a semiconductor device, and particularly, to a stacked semiconductor device in which a plurality of chips are stacked 3-dimensionally and a method of fabricating the stacked semiconductor device.

2. Description of Related Art

Recently, through silicon vias (TSVs) have been used as communication means for high-speed communication between semiconductor integrated circuits, and research on stacked semiconductor devices in which memory chips are stacked 3-dimensionally has progressed.

In a stacked semiconductor device, defects may be generated in semiconductor chips due to heat or pressure generated from a process of stacking the semiconductor chips.

### SUMMARY

Example embodiments of the inventive concepts provide a stacked semiconductor device with improved reliability.

Example embodiments of the inventive concepts also provide a method of fabricating a stacked semiconductor device with improved reliability.

The technical objectives of the inventive concepts are not limited to the above disclosure; other objectives may become apparent to those of ordinary skill in the art based on the following descriptions.

In accordance with example embodiments of the inventive concepts, a stacked semiconductor device may include a first semiconductor chip including a plurality of first through silicon vias (TSVs) and at least one second semiconductor chip below the first semiconductor chip. In example embodiments, the at least one second semiconductor chip may include a plurality of second TSVs and the at least one second semiconductor chip may be thinner than the first semiconductor chip.

In accordance with example embodiments of the inventive concepts, a method of fabricating a stacked semiconductor device may include preparing a first semiconductor chip including a plurality of first through silicon vias (TSVs) and stacking at least one second semiconductor chip including a plurality of second TSVs above the first semiconductor chip, wherein the at least one second semiconductor chip is thinner than the first semiconductor chip.

In accordance with example embodiments of the inventive concepts, a stacked semiconductor device may include a first semiconductor chip including a first plurality of through silicon vias, at least one second semiconductor chip below the first semiconductor chip, the at least one second semiconductor chip including a second plurality of through silicon vias, a plurality of internal connecting terminals between the first semiconductor chip and the at least one second semiconductor chip electrically connecting the first and second pluralities of through silicon vias, a main substrate below the at least one second semiconductor conductor chip, and at least one connecting terminal between the at least one second semiconductor chip and the main substrate electrically connecting the at least one second semiconductor chip to the main substrate, wherein a thickness of the first semiconductor chip is thicker than a thickness of the at least one second semiconductor chip.

In accordance with example embodiments of the inventive concepts, a stacked semiconductor device may include a first semiconductor chip and at least one second semiconductor chip.

The first semiconductor chip may include a plurality of first through silicon vias (TSVs). The at least one second semiconductor chip may include a plurality of second TSVs. The at least one second semiconductor chip may be stacked above the first semiconductor chip and may be thinner than the first semiconductor chip.

In example embodiments, each of the first TSVs may be formed between both surfaces of the first semiconductor chip.

In example embodiments, each of the first TSVs may be formed between a surface and an internal portion of the first semiconductor chip.

In example embodiments, an uppermost semiconductor chip of the at least one second semiconductor chip may be electrically coupled to a main substrate through external connecting terminals.

In example embodiments, each of the external connecting terminals may include a conductive bump or a solder ball.

In example embodiments, the uppermost semiconductor chip of the at least one second semiconductor chip may be electrically coupled to a processor chip.

In example embodiments, the first semiconductor chip and the at least one second semiconductor chip may be same kinds of semiconductor chips.

In example embodiments, the first semiconductor chip and the at least one second semiconductor chip may be different kinds of semiconductor chips from each other.

In example embodiments, a first distance between the first semiconductor chip and a semiconductor chip adjacent to the first semiconductor chip among the at least one second semiconductor chip may be longer than a second distance between the second semiconductor chips.

In example embodiments, the first distance and the second distance may be adjusted according to a size of a conductive bump.

In example embodiments, the stacked semiconductor device may further comprise internal connecting terminals aligned with the first TSVs on the first semiconductor chip.

In example embodiments, each of the internal connecting terminals may include a conductive bump or a solder ball.

In example embodiments, the stacked semiconductor device may further comprise an encapsulant covering the first semiconductor chip and the at least one second semiconductor chip.

In example embodiments, the encapsulant may cover sidewalls of the first semiconductor chip and the at least one second semiconductor chip, and one surface of the first semiconductor chip is not covered with the encapsulant.

In example embodiments, the stacked semiconductor device may further comprise an auxiliary substrate disposed on one surface of the first semiconductor chip.

In accordance with example embodiments of the inventive concepts, a stacked semiconductor device may include a main substrate, an auxiliary substrate, a first semiconductor chip and at least one second semiconductor chip.

The first semiconductor chip may include a plurality of first TSVs. The at least one second semiconductor chip may include a plurality of second TSVs, and may be formed between the main substrate and the first semiconductor chip. The at least one second semiconductor chip may be stacked above the first semiconductor chip and may be thinner than the first semiconductor chip.

In example embodiments, the stacked semiconductor device may further comprise an encapsulant covering the first semiconductor chip and the at least one second semiconductor chip.

In example embodiments, the encapsulant may surround the auxiliary substrate.

In accordance with example embodiments of the inventive concepts, a method of fabricating a stacked semiconductor device may include preparing a first semiconductor chip including a plurality of first TSVs and stacking at least one second semiconductor chip including a plurality of second TSVs above the first semiconductor chip. In example embodiments, the at least one second semiconductor chip may be thinner than the first semiconductor chip.

In example embodiments, the method may further include covering the first semiconductor chip and the at least one second semiconductor chip with an encapsulant.

A stacked semiconductor device in accordance with example embodiments of the inventive concepts may include a first semiconductor device having TSVs, and second semiconductor devices having TSVs and thinner than the first semiconductor device. Further, a first distance between the first semiconductor chip and a semiconductor chip adjacent to the first semiconductor chip among the second semiconductor chips may be longer than a second distance between the second semiconductor chips.

Therefore, the stacked semiconductor device according to example embodiments of the inventive concepts may easily emit heat generated during stacking of the stacked semiconductor device, and the thicker semiconductor chip may function as a holder. Therefore, the stacked semiconductor device may decrease fault rates of reliability due to a mismatch of a thermal expansion coefficient and a thermal budget, and a production yield may be improved.

### BRIEF DESCRIPTION OF THE DRAWINGS

The foregoing and other features and advantages of the inventive concepts will be apparent from the more particular description of example embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1 is a simplified cross-sectional view illustrating a stacked semiconductor device in accordance with example embodiments of the inventive concepts;

FIG. 2 is a simplified cross-sectional view illustrating a stacked semiconductor device in accordance with example embodiments of the inventive concepts;

FIG. 3 is a cross-sectional view illustrating a packaged device of the stacked semiconductor device of FIG. 1 in accordance with example embodiments of the inventive concepts;

FIG. 4 is an enlarged view of a portion K of FIG. 3;

FIG. 5 is a cross-sectional view illustrating a packaged device of the stacked semiconductor device of FIG. 1 in accordance with example embodiments of the inventive concepts;

FIG. 6 is a cross-sectional view illustrating a packaged device of the stacked semiconductor device of FIG. 1 in accordance with example embodiments of the inventive concepts;

FIG. 7 is a cross-sectional view illustrating a packaged device of the stacked semiconductor device of FIG. 1 in accordance with example embodiments of the inventive concepts;

FIGS. 8 through 11 are cross-sectional views illustrating a method of fabricating the packaged device of the stacked semiconductor device in accordance with example embodiments of the inventive concepts;

FIGS. 12 through 14 are cross-sectional views illustrating a method of fabricating the packaged device of the stacked semiconductor device in accordance with example embodiments of the inventive concepts;

FIG. 15 is a simplified cross-sectional view illustrating a stacked semiconductor device in accordance with example embodiments of the inventive concepts;

FIG. 16 is a simplified cross-sectional view illustrating a stacked semiconductor device in accordance with example embodiments of the inventive concepts;

FIG. 17 is a plan view illustrating a semiconductor module including stacked semiconductor devices according to example embodiments of the inventive concepts; and

FIG. 18 is a block diagram illustrating an example of an electronic system including a stacked semiconductor device in accordance with example embodiments of the inventive concepts.

### DETAILED DESCRIPTION OF EXAMPLE EMBODIMENTS

Example embodiments will now be described more fully with reference to the accompanying drawings in which example embodiments are shown. The inventive concepts may, however, be embodied in different forms and should not be construed as limited to example embodiments as set forth herein. Rather, example embodiments are provided so that this disclosure is thorough and complete and fully conveys the inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers that may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing example embodiments only and is not intended to be limiting of the inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the inventive concepts.

Unless otherwise defined, all terms (including technical and scientific teens) used herein have the same meaning as commonly understood by one of ordinary skill in the art to which the inventive concepts belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

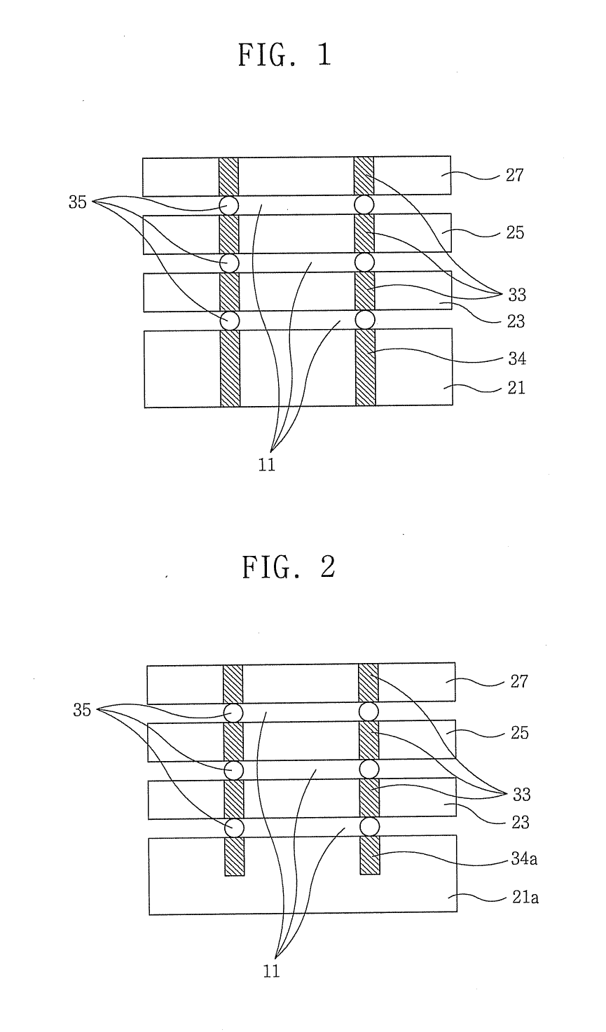

FIG. 1 is a simplified cross-sectional view illustrating a stacked semiconductor device in accordance with example embodiments of the inventive concepts.

Referring to FIG. 1, the stacked semiconductor device may include a first semiconductor chip 21 and at least one second semiconductor chip 23, 25 and 27.

The first semiconductor chip 21 may include first through silicon vias (TSVs) 34 and the second semiconductor chips 23, 25 and 27 may include second TSVs 33. In example embodiments, the second semiconductor chips 23, 25, and 27 may be stacked above the first semiconductor chip 21 and may be thinner than the first semiconductor chip 21. Furthermore, the first TSVs 34 and the second TSVs 33 may be vertically aligned with one another as shown in FIG. 1.

In the stacked semiconductor device shown in FIG. 1, the first TSVs 34 may be formed between both surfaces (upper and lower surfaces) of the first semiconductor chip 21. As will be described hereinafter, adhesive layers 11 may be interposed between the first semiconductor chip 21 and a second semiconductor chip 23 of the second semiconductor chips 23, 25 and 27 and between the second semiconductor chips 23, 25 and 27. Further, internal connecting terminals 35 electrically connecting the first semiconductor chip 21 and the second semiconductor chips 23, 25 and 27 may be interposed between the first semiconductor chip 21 and the second semiconductor chip 23 of the second semiconductor chips 23, 25 and 27 and between the second semiconductor chips 23, 25 and 27. The internal connecting terminals 35 may be aligned with TSVs 33 and 34, and may include a conductive bump, a solder ball, or a conductive spacer.

As will be described hereinafter, a lower surface of the first semiconductor chip 21 may be coupled to a dummy substrate, and an upper surface of an uppermost second semiconductor chip 27 of the second semiconductor chips 23, 25 and 27 may be electrically connected to a main substrate through external connecting terminals. The first semiconductor chip 21 may function as a support during a fabrication process of the stacked semiconductor device. Further, the upper surface of the uppermost semiconductor chip 27 of the second semiconductor chips 23, 25 and 27 may be electrically connected to a processor chip through the external connecting terminals.

The first semiconductor chip and the at least one second semiconductor chip may be the same kinds of semiconductor chips or different kinds of semiconductor chips.

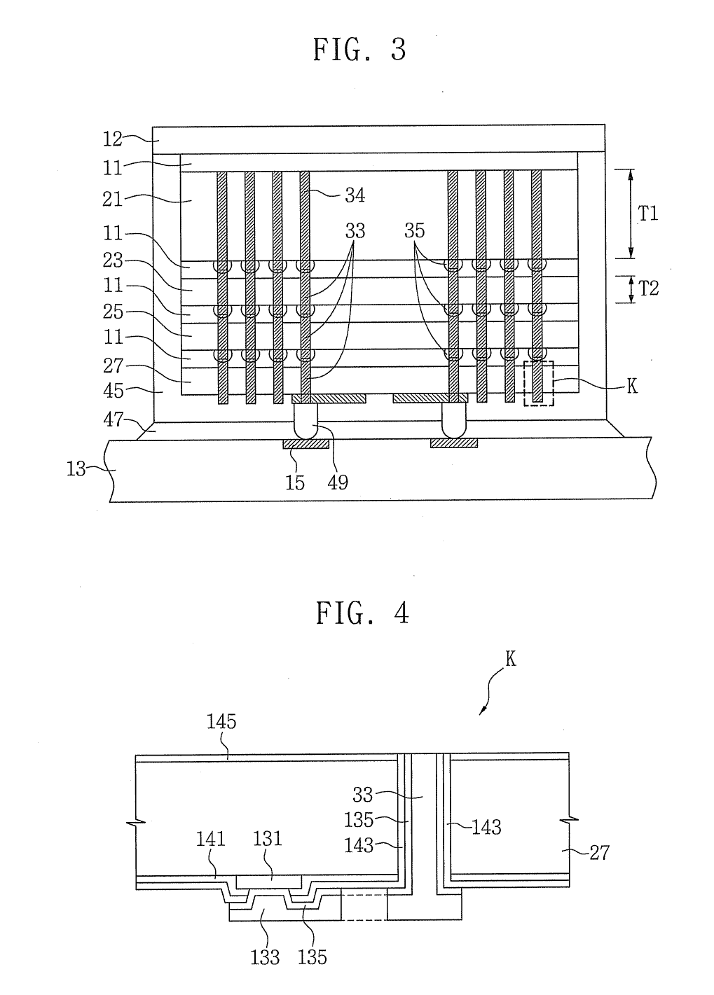

FIG. 2 is a simplified cross-sectional view illustrating a stacked semiconductor device in accordance with example embodiments of the inventive concepts.

Referring to FIG. 2, the first TSVs 34a may be formed in the first semiconductor chip 21a so that they do not penetrate the first semiconductor chip 21a. In example embodiments, the first TSV's may be formed between a surface, for example, an upper surface of the first semiconductor chip 21a, and an internal portion of the first semiconductor chip 21a.

The first TSVs 34 and 34a included in the first semiconductor chip 21 or 21a shown in FIG. 1 and FIG. 2 may be used for not only transmitting signals but also for adjusting impedance of input/output lines of the stacked semiconductor device.

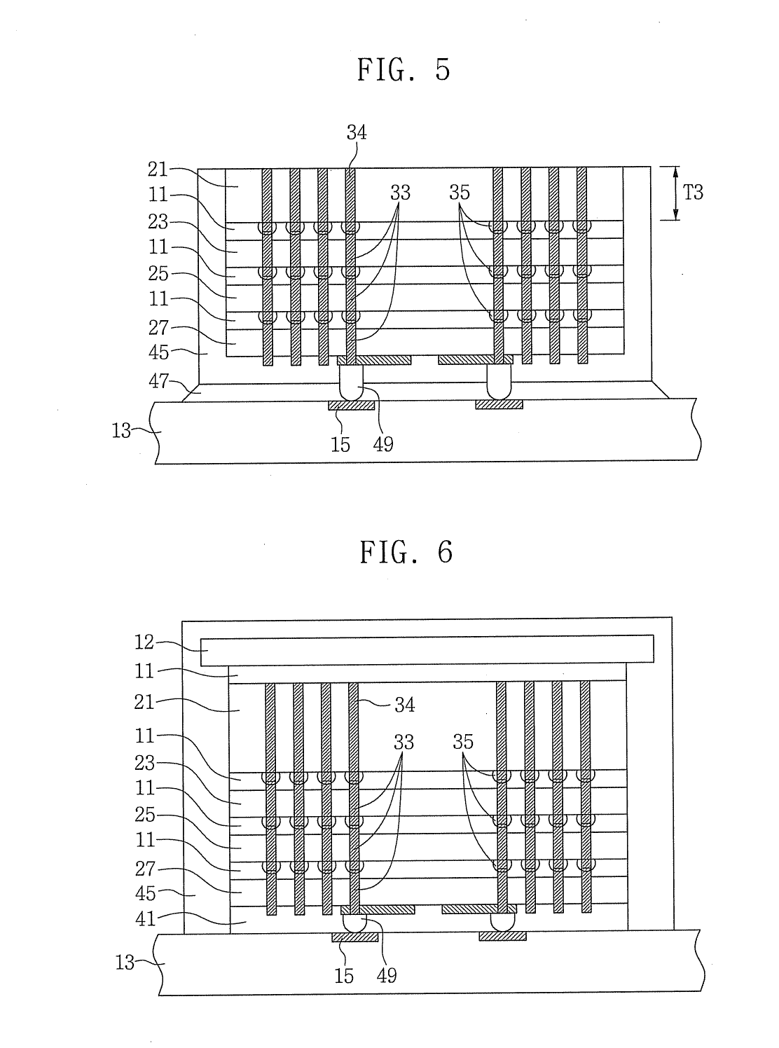

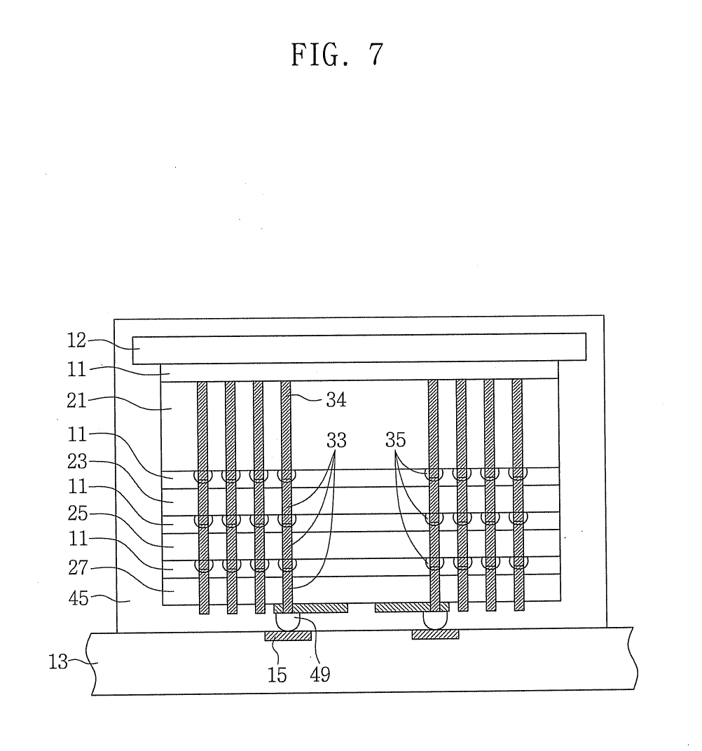

FIG. 3 is a cross-sectional view illustrating a packaged device of the stacked semiconductor device of FIG. 1 in accordance with example embodiments of the inventive concepts, and FIG. 4 is an enlarged view of a part K of FIG. 3.

Referring to FIG. 3 and FIG. 4, the stacked semiconductor device in accordance with example embodiments of the inventive concepts may include a first semiconductor chip 21, and second to fourth semiconductor chips 23, 25 and 27 stacked below the first semiconductor chip 21. The first to fourth semiconductor chips 21, 23, 25 and 27 may be covered with an encapsulant 45. The first semiconductor chip 21 may be disposed on an auxiliary substrate 12. Further, a main substrate 13 adjacent to (or below) the fourth semiconductor chip 27 may be provided. An underfill 47 may be interposed between the main substrate 13 and the encapsulant 45. The first to fourth semiconductor chips 21, 23, 25 and 27 may be connected to the main substrate 13 through connecting terminals 35 and 49 and the TSVs 33 and 34. The adhesive layers 11 may be interposed between the first to fourth semiconductor chips 21, 23, 25 and 27, and between the first semiconductor chip 21 and the auxiliary substrate 12.

The second to fourth semiconductor chips 23, 25 and 27 may be stacked in order below the first semiconductor chip 21 with the semiconductor chip 23 being arranged closest to the semiconductor chip 21 and the semiconductor chip 27 being arranged furthest from the first semiconductor chip 21. The first semiconductor chip 21 may have a first thickness T1, and the second to fourth semiconductor chips 23, 25 and 27 may have a second thickness T2. The second thickness T2 may be smaller than the first thickness T1. For example, the first thickness T1 may be two times to three hundred times the second thickness T2. In example embodiments, the first thickness T1 may be larger than a length of the TSVs 33. For example, the first thickness T1 may be two times to three hundred times the length of the TSVs 33.

As shown in FIG. 4, the fourth semiconductor chip 27 may include a redistribution layer 133 and the TSVs 33. A chip pad 131 may be disposed on a front side (for example, a bottom side) of the fourth semiconductor chip 27. The front side of the fourth semiconductor chip 27 may be covered with a first insulating layer 141, and a back side (for example, a top side) of the fourth semiconductor chip 27 may be covered with a second insulating layer 145. The redistribution layer 133 may be formed on the first insulating layer 141. The redistribution layer 133 may be electrically connected to active devices (not shown) in the fourth semiconductor chip 27 via the chip pad 131. A barrier metal layer 135 may be interposed between the redistribution layer 133 and the first insulating layer 141. The barrier metal layer 135 may be contacted with the redistribution layer 133 and the chip pad 131.

The TSVs 33 may be exposed on the front and back sides through the fourth semiconductor chip 27. A third insulating layer 143 may be interposed between the TSVs 33 and the fourth semiconductor chip 27. The TSV 33 may be insulated from the fourth semiconductor chip 27. The barrier metal layer 135 may be interposed between the TSV 33 and the third insulating layer 143. The barrier metal layer 135 may be in contact with the TSV 33. The TSV 33 may project from the front surface of the fourth semiconductor chip 27. The TSV 33 may be at substantially the same plane as the back side of the fourth semiconductor chip 27.

The chip pad 131 may include at least one selected from the group consisting of aluminum (Al), copper (Cu), tungsten (W), tungsten nitride (WN), titanium (Ti), titanium nitride (TiN), tantalum (Ta), tantalum nitride (TaN), and a combination thereof. The barrier metal layer 135 may be formed of at least one selected from the group consisting of Ti, TiN, and a combination thereof. The TSV 33 and the redistribution layer 133 may include at least one selected from the group consisting of W, WN, Ti, TiN, Ta, TaN, Al, Cu, and a combination thereof. The first to third insulating layers 141, 143 and 145 may include at least one selected from the group consisting of a silicon oxide layer, a silicon nitride layer, a silicon oxynitride layer, a low-k dielectric layer, and a combination thereof.

In example embodiments, the TSV 33 may be exposed on substantially the same plane as the front side (bottom side) of a semiconductor chip or may be located at a plane lower than the front side. In addition, the TSV 33 may project from the back side of a semiconductor chip or may be located at a plane lower than the back side of the semiconductor chip.

In example embodiments, the TSV 33 may be in contact with the redistribution layer 133. In this case, the TSV 33 may be in electrical contact with active devices (not shown) in the fourth semiconductor chip 27 via the redistribution layer 133 and the chip pad 131.

As shown in FIG. 3, a plurality of TSVs 33 and 34 may be disposed in the first to fourth semiconductor chips 21, 23, 25 and 27 at intervals that may or may not be predetermined. Internal connecting terminals 35 may be provided on the first semiconductor chip 21. The internal connecting terminals 35 may be in electrical contact with active devices (not shown) in the first semiconductor chip 21. Each of the internal connecting terminals 35 may be one selected from the group consisting of a conductive bump, a solder ball, a conductive spacer, and a combination thereof.

The second semiconductor chip 23 may include the plurality of TSVs 33. One ends of the TSVs 33 may be in contact with the internal connecting terminals 35, respectively. The adhesive layer 11 may be interposed between the first and second semiconductor chips 21 and 23. The internal connecting terminals 35 may be attached to the other ends of the TSVs 33, respectively. Each of the internal connecting terminals 35 may be one selected from the group consisting of a conductive bump, a solder ball, a conductive spacer, and a combination thereof.

The third semiconductor chip 25 may also include the plurality of TSVs 33. One ends of the TSVs 33 may be in contact with the internal connecting terminals 35. The adhesive layer 11 may be interposed between the second and third semiconductor chips 23 and 25. The internal connecting terminals 35 may be attached to the other ends of the TSVs 33, respectively.

The fourth semiconductor chip 27 may also include the plurality of TSVs 33. One ends of the TSVs 33 may be in contact with the internal connecting terminals 35. The adhesive layer 11 may be interposed between the third and fourth semiconductor chips 25 and 27. The other ends of the TSVs 33 may be in contact with external connecting terminals 49. Each of the external connecting terminals 49 may be one selected from the group consisting of a conductive bump, a solder ball, a conductive spacer, a pin grid array (PGA), a lead grid array (LGA), and a combination thereof.

The first semiconductor chip 21 may be attached to a surface of the auxiliary substrate 12 using the adhesive layer 11. In example embodiments, the auxiliary substrate 12 may be a sub-board. The encapsulant 45 may be formed to cover the auxiliary substrate 12 and surround the first to fourth semiconductor chips 21, 23, 25 and 27. In this case, the external connecting terminals 49 may be exposed through the encapsulant 45. The encapsulant 45 may be formed of an epoxy molding compound (EMC).

The main substrate 13 (which may serve as a main board) facing the auxiliary substrate 12 may be provided. The main substrate 13 may include a substrate pad 15 (for example, a board pad). The underfill 47 may be formed between the main substrate 13 and the encapsulant 45. The external connecting terminals 49 may be in contact with the substrate pad 15 through the encapsulant 45 and the underfill 47.

As a result, the first to fourth semiconductor chips 21, 23, 25 and 27 may be in electrical contact with the main substrate 13 via the internal connecting terminals 35, the TSVs 33, and the external connecting terminals 49.

The auxiliary board 12 may be a dummy substrate. In this case, the auxiliary board 12 may be insulated from the first to fourth semiconductor chips 21, 23, 25 and 27. The main substrate 13 may have a first surface adjacent to the external connecting terminals 49 and a second surface facing the first surface. Further, the main substrate 13 may correspond to a motherboard of an electronic system.

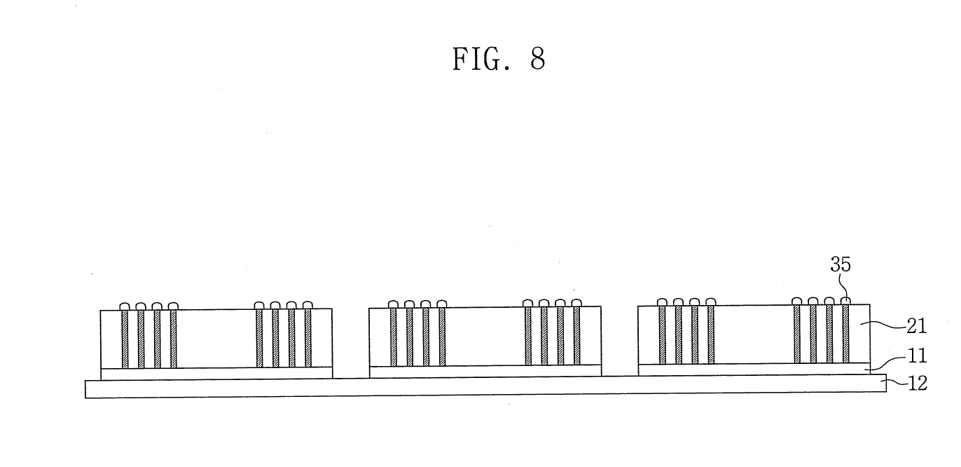

FIG. 5 is a cross-sectional view illustrating a packaged device of the stacked semiconductor device of FIG. 1 in accordance with example embodiments of the inventive concepts.

Referring to FIG. 5, a multi-chip package according to example embodiments of the inventive concepts may include first to fourth semiconductor chips 21, 23, 25 and 27, an encapsulant 45, a main substrate 13 (for example, a main board), a substrate pad 15 (for example, a board pad), an underfill 47, connecting terminals 35, 49, TSVs 33 and 34, and an adhesive layer 11. Only differences from the description with reference to FIG. 3 will be briefly described below.

The first semiconductor chip 21 may have a third thickness T3. The third thickness T3 may be greater than the second thickness T2 and less than the first thickness T1.

To be specific, the multi-chip package described with reference to FIG. 1 may be processed, thereby removing the auxiliary substrate 12 and the adhesive layer 11. Subsequently, one surface of the first semiconductor chip 21 may be partially removed, thereby reducing a thickness. In this case, the encapsulant 45 may also be partially removed. The first semiconductor chip 21 and the encapsulant 45 may be exposed on the same plane.

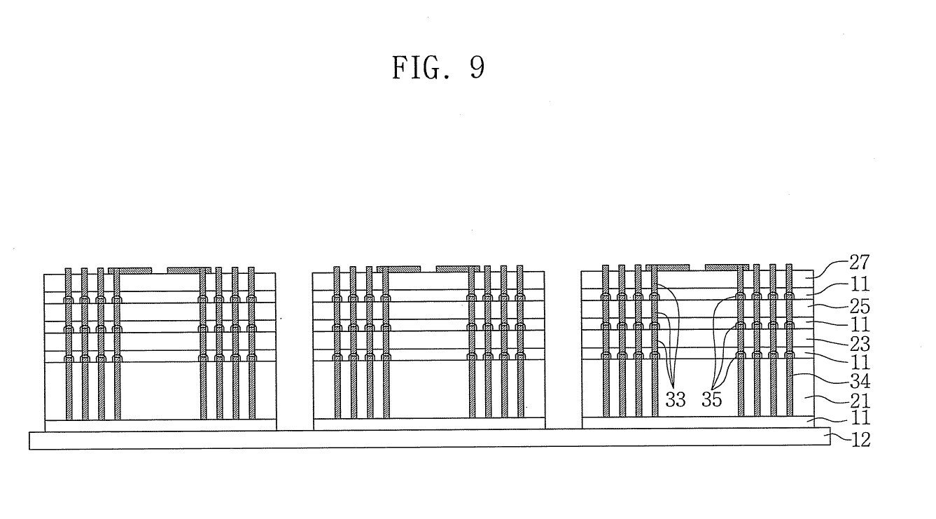

FIG. 6 is a cross-sectional view illustrating a packaged device of the stacked semiconductor device of FIG. 1 in accordance with example embodiments of the inventive concepts.

Referring to FIG. 6, a multi-chip package according to example embodiments of the inventive concepts may include first to fourth semiconductor chips 21, 23, 25 and 27, an encapsulant 45, an auxiliary board 12 (for example, a sub-board), a main substrate 13 (for example, a main board), a substrate pad 15 (for example a board pad), connecting terminals 35 and 49, TSVs 33 and 34, and an adhesive layer 11. Only differences from the descriptions with reference to FIGS. 3 and 4 will be briefly described below.

The encapsulant 45 may cover the main substrate 13, the auxiliary substrate 12, and the first to fourth semiconductor chips 21, 23, 25 and 27. An adhesive layer 41 may be interposed between the fourth semiconductor chip 27 and the main substrate 13. That is, the adhesive layer 41 may be in contact with the main substrate 13 and the fourth semiconductor chip 27. In this case, external connecting terminals 49 may be in contact with the substrate pad 15 through the adhesive layer 41.

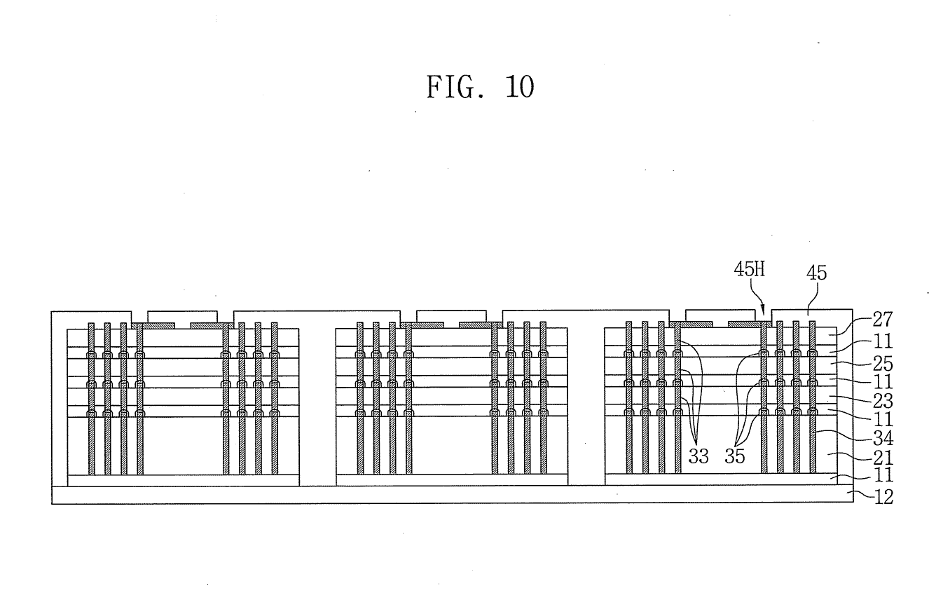

FIG. 7 is a cross-sectional view illustrating a packaged device of the stacked semiconductor device of FIG. 1 in accordance with example embodiments of the inventive concepts.

Referring to FIG. 7, a multi-chip package according to example embodiments of the inventive concepts may include first to fourth semiconductor chips 21, 23, 25 and 27, an encapsulant 45, an auxiliary board 12 (for example, a sub-board), a main substrate (for example, a main board), a substrate pad 15 (for example, a board pad), connecting terminals 35 and 49, TSVs 33 and 34, and adhesive layers 11. Only differences from the descriptions with reference to FIGS. 3 through 6 will be briefly described below.

The encapsulant 45 may cover the main substrate 13, and the auxiliary substrate 12 and the first to fourth semiconductor chips 21, 23, 25 and 27. The encapsulant 45 may be interposed between the fourth semiconductor chip 27 and the main substrate 13. That is, the encapsulant 45 may be in contact with the main substrate 13 and the fourth semiconductor chip 27. In this case, external connecting terminals 49 may be in contact with the substrate pad 15 through the encapsulant 45.

In example embodiments, the second to fourth semiconductor chips 23, 25 and 27 may be referred to as thin semiconductor chips. Further, one or more than one semiconductor chip may be stacked on the first semiconductor chip 21.

According to example embodiments of the inventive concepts, due to the configuration of the first to fourth semiconductor chips 21, 23, 25 and 27, the internal connecting terminals 35, the TSVs 33, the internal connecting terminals 35 and the external connecting terminals 49, a reliability defect caused by the difference of coefficients of thermal expansion (CTEs) may be fundamentally improved. Further, due to the configuration of the auxiliary substrate 12, the first to fourth semiconductor chips 21, 23, 25 and 27, the internal connecting terminals 35, the TSVs 33, internal connecting terminals 33, the external connecting terminals 49, and the main substrate 13, a reliability defect caused by the difference of CTEs and thermal budget may be significantly reduced.

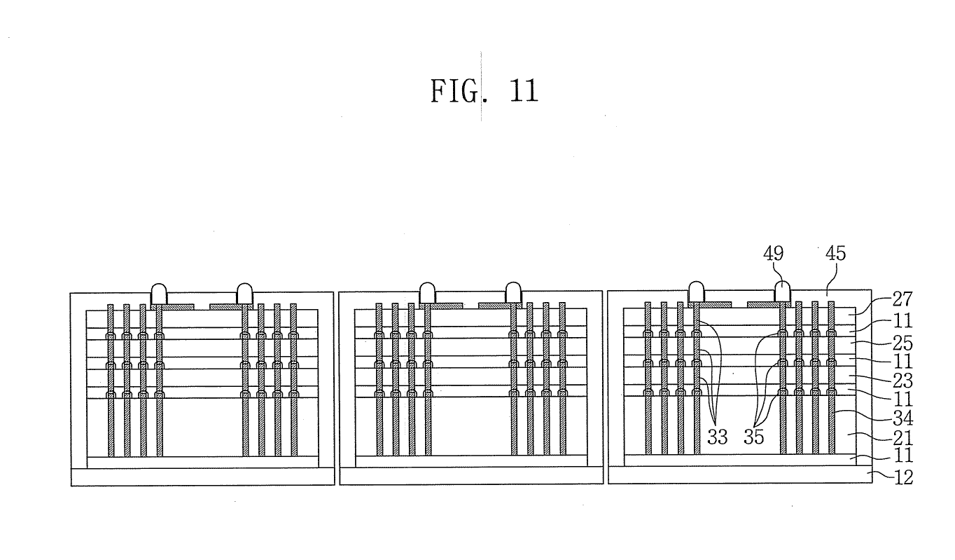

FIGS. 8 through 11 are cross-sectional views illustrating a method of fabricating the packaged device of the stacked semiconductor device in accordance with example embodiments of the inventive concepts.

Referring to FIG. 8, first semiconductor chips 21 may be attached to a surface of an auxiliary board 12 (for example, a sub-board) at intervals using an adhesive layer 11. In example embodiments, the intervals may or may not be predetermined. Internal connecting terminals 35 may be formed on surfaces of the first semiconductor chip 21. The internal connecting terminals 35 may be formed before or after the first semiconductor chips 21 are attached to the sub-board 12.

The auxiliary board 12 may be formed as a flexible printed circuit board, a rigid printed circuit board, or a combination thereof. The first semiconductor chip 21 may be formed using a silicon wafer or a silicon on insulator (SOI) wafer. The first semiconductor chip 21 may include a volatile memory chip (for example, a DRAM or an SRAM), a non-volatile memory chip (for example, a flash memory), a phase change memory, an MRAM or an RRAM, or a combination thereof. In example embodiments, the first semiconductor chip 21 may include a logic device and/or non-memory devices, for example, a microprocessor.

The first semiconductor chip 21 may include components similar to the redistribution layer 133 of FIG. 4 and the chip pad 131 of FIG. 4. In this case, the internal connecting terminals 35 may be formed on the redistribution layer 133 of FIG. 4. The internal connecting terminals 35 may be formed of one selected from the group consisting of a conductive bump, a solder ball, a conductive spacer, and a combination thereof. For example, the internal connecting terminals 35 may be formed using a micro bump having a relatively small size.

In example embodiments, the auxiliary board 12 and the adhesive layer 11 may be omitted.

Referring to FIG. 9, second to fourth semiconductor chips 23, 25 and 27 may be sequentially attached to the first semiconductor chip 21 using adhesive layers 11. The second to fourth semiconductor chips 23, 25 and 27 may include a plurality of TSVs 33. The TSVs 33 may be arranged with the internal connecting terminals 35, respectively. The internal connecting terminals 35 may be formed between the second to fourth semiconductor chips 23, 25 and 27. The internal connecting terminals 35 may be in contact with the TSVs 33. The internal connecting terminals 35 may be formed of one selected from the group consisting of a conductive bump, a solder ball, a conductive spacer, and a combination thereof.

The second to fourth semiconductor chips 23, 25 and 27 may be the same or different types of chips. Further, the second to fourth semiconductor chips 23, 25 and 27 may be the same or different types of chips from the first semiconductor chips 21. The second to fourth semiconductor chips 23, 25 and 27 may include a volatile memory chip (for example, a DRAM or an SRAM), a non-volatile memory chip (for example, a flash memory), a phase change memory, an MRAM or an RRAM, or a combination thereof. The second to fourth semiconductor chips 23, 25 and 27 may include a logic device and/or non-memory devices, for example a microprocessor.

Referring to FIG. 10, an encapsulant 45 covering the first to fourth semiconductor chips 21, 23, 25 and 27 may be formed on the auxiliary board 12. The encapsulant 45 may be formed of an epoxy molding compound (EMC) containing a resin and a filler. The encapsulant 45 may cover sidewalls and top surfaces of the first to fourth semiconductor chips 21, 23, 25 and 27. Openings 45H exposing the TSVs 33 through the encapsulant 45 may be formed. The openings 45H may be formed using a laser drilling technique.

Referring to FIG. 11, external connecting terminals 49 may be formed on the TSVs 33 exposed through the openings 45H. Further, the encapsulant 45 and the auxiliary board 12 may be divided into appropriate sizes using the singulation process.

The external connecting terminals 49 may be formed of one selected from the group consisting of a conductive bump, a solder ball, a conductive spacer, a PGA, an LGA, and a combination thereof. The external connecting terminals 49 may be larger than the internal connecting terminals 35. For example, the external connecting terminals 49 may be 2 to 10 times larger than the internal connecting terminals 35.

In example embodiments, similar to that shown in FIG. 5, a process of removing the auxiliary board 12 and the adhesive layer 11 may be further performed. The process of removing the auxiliary 12 and the adhesive layer 11 may be performed after the encapsulant 45 is formed. For example, the process of removing the auxiliary board 12 and the adhesive layer 11 may be performed before the openings 45H are formed. Further, the process of removing the auxiliary 12 and the adhesive layer 11 may be performed before or after the singulation process is performed. Subsequently, one surface of the first semiconductor chip 21 may be partially removed, thereby reducing a thickness. In this case, the encapsulant 45 may also be partially removed. The first semiconductor chip 21 and the encapsulant 45 may be exposed on the same plane. Here, the partial removal of the side of the first semiconductor chip 21 to reduce the thickness may be performed using chemical-mechanical polishing (CMP) and/or etch-back.

In example embodiments, similar to that shown in FIG. 5, the stacked semiconductor device fabricated above may be attached to the main substrate 13, and applied in various ways as described with reference to FIG. 7.

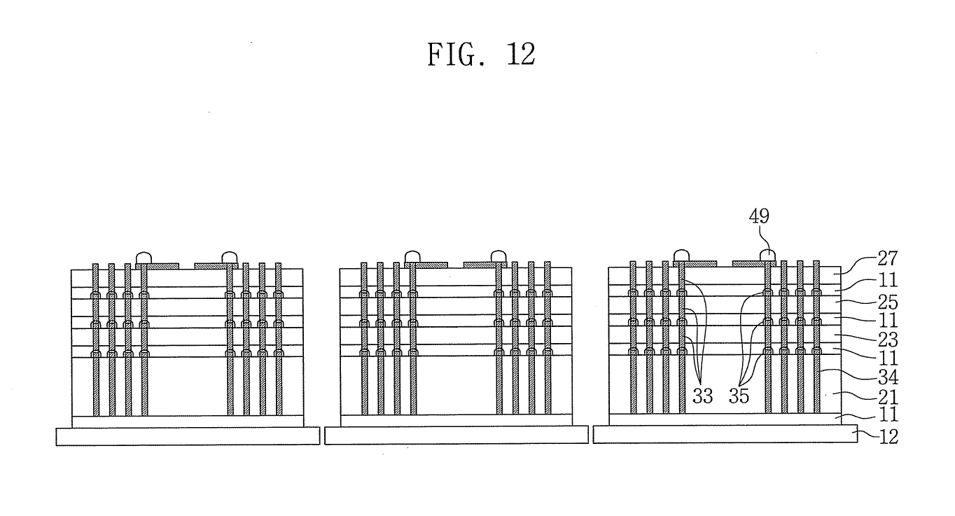

FIGS. 12 through 14 are cross-sectional views illustrating a method of fabricating the packaged device of the stacked semiconductor device in accordance with example embodiments of the inventive concepts.

Referring to FIG. 12, a first semiconductor chip 21 may be attached to a surface of an auxiliary board 12 at intervals using an adhesive layer 11. In example embodiments, the intervals may or may not be predetermined. Internal connecting terminals 35 may be formed on surfaces of the first semiconductor chip 21. Second to fourth semiconductor chips 23, 25 and 27 may be sequentially attached to the surfaces of the first semiconductor chip 21 using adhesive layers 11. The second to fourth semiconductor chips 23, 25 and 27 may include a plurality of TSVs 33. The TSVs 33 may be aligned with the internal connecting terminals 35, respectively. The internal connecting terminals 35 may be formed between the second to fourth semiconductor chips 23, 25 and 27.

External connecting terminals 49 may be formed on the fourth semiconductor chips 27. The external connecting terminals 49 may be attached to the TSVs 33. In addition, the auxiliary board 12 may be divided into appropriate sizes using a singulation process.

Referring to FIG. 13, a main substrate 13 may be attached to surfaces of the fourth semiconductor chips 27 using adhesive layers 11. The external connecting terminals 49 may be electrically connected to the main substrate 13. The main substrate 13 may be formed as a flexible printed circuit board, a rigid printed circuit board, or a combination thereof. The main substrate 13 may include substrate pads (not shown). In this case, the external connecting terminals 49 may be connected to the substrate pads (not shown) through the adhesive layers 11.

An encapsulant 45 covering the auxiliary board 12 and the first to fourth semiconductor chips 21, 23, 25 and 27 may be formed on the main substrate 13. The encapsulant 45 may cover sidewalls and a lower surface of the auxiliary 12 and sidewalls of the first to fourth semiconductor chips 21, 23, 25 and 27. The encapsulant 45 and the main substrate 13 may be divided into appropriate sizes using the singulation process.

The example device may have a similar configuration to that shown in FIG. 6.

Referring to FIG. 14, according to example embodiments, the encapsulant 45 may extend between the main substrate 13 and the fourth semiconductor chip 27. In this case, the external connecting terminals 49 may be electrically connected to the main substrate 13 through the encapsulant 45. This device may have a similar configuration to that shown in FIG. 7.

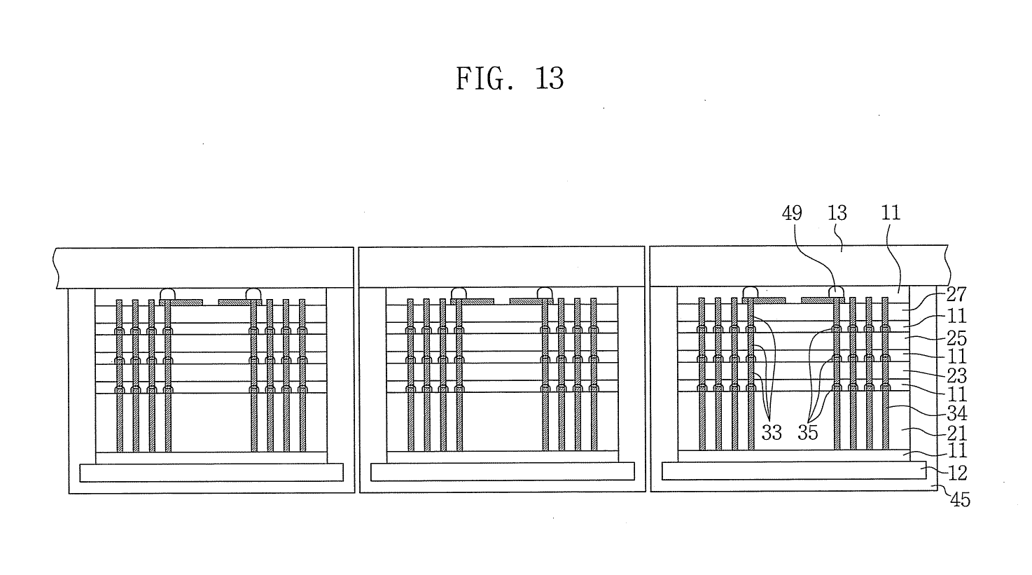

FIG. 15 is a simplified cross-sectional view illustrating a stacked semiconductor device in accordance with example embodiments of the inventive concepts.

In FIG. 15, a first distance between the first semiconductor chip 21 and a semiconductor chip 23 adjacent to the first semiconductor chip 21 among the second semiconductor chips 23, 25 and 27 may be longer than a second distance between the second semiconductor chips. The first distance and the second distance may be adjusted according to a size of conductive bumps 35 and 36. Adhesive layers 11a may be interposed between the first semiconductor chip 21 and the semiconductor chip 23 adjacent to the first semiconductor chip 21 among the second semiconductor chips 23, 25 and 27.

When the first distance between the first semiconductor chip 21 and the semiconductor chip 23 adjacent to the first semiconductor chip 21 among the second semiconductor chips 23, 25 and 27 is longer than the second distance between the second semiconductor chips as shown in FIG. 15, heat generated during a stacking process may be easily emitted.

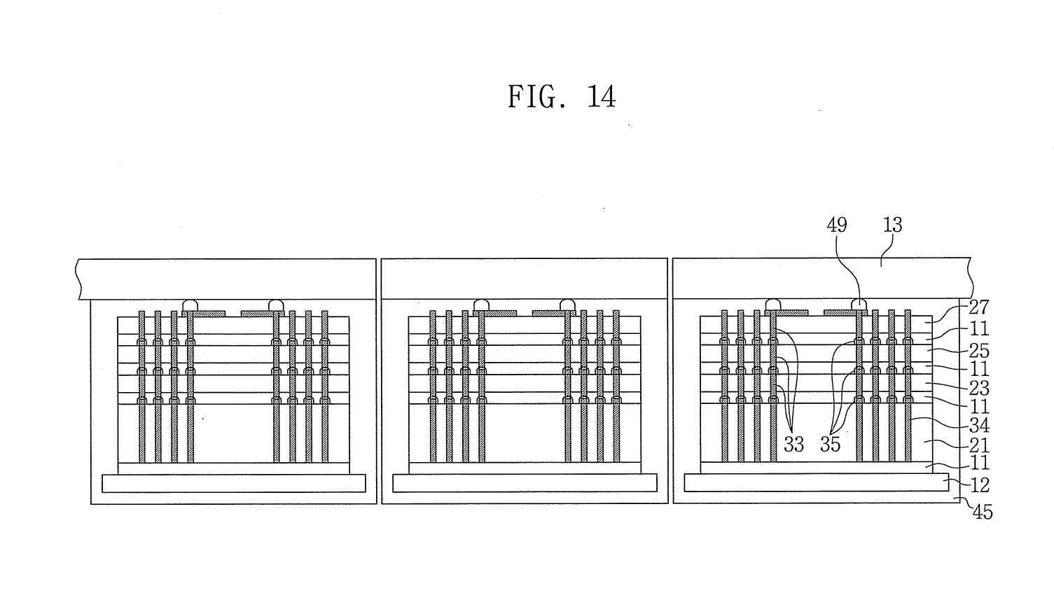

FIG. 16 is a simplified cross-sectional view illustrating a stacked semiconductor device in accordance with example embodiments of the inventive concept.

Referring to FIG. 16, the stacked semiconductor device includes a plurality of semiconductor chips 51, 53, 55 and 57. In the example of FIG. 16, semiconductor chips having different thicknesses may be stacked at arbitrary positions.

The semiconductor chips 51 and 53 include first TSVs 60 and have a first thickness. The semiconductor chips 55 and 57 include second TSVs 59, and have a second thickness larger than the first thickness.

Adhesive layers 11 may be interposed between the semiconductor chips 51, 53, 55 and 57. Further, internal connecting terminals 35 to electrically connect the semiconductor chips 51, 53, 55 and 57 may be interposed between the semiconductor chips 51, 53, 55 and 57. The internal connecting terminals 35 may be aligned with TSVs 59 and 60, and may include a conductive bump, a solder ball or a conductive spacer.

As described hereinafter, a lower surface of the first semiconductor chip 21 may be coupled to a dummy substrate, and an upper surface of an uppermost semiconductor chip 27 of the second semiconductor chips 23, 25 and 27 may be electrically connected to a main substrate through external connecting terminals. The first semiconductor chip 21 may function as a support during a fabrication process of the stacked semiconductor device. Further, the upper surface of the uppermost semiconductor chip 27 of the second semiconductor chips 23, 25 and 27 may be electrically connected to a processor chip through the external connecting terminals.

The first semiconductor chip and the at least one second semiconductor chip may be the same kinds of semiconductor chips or different kinds of semiconductor chips.

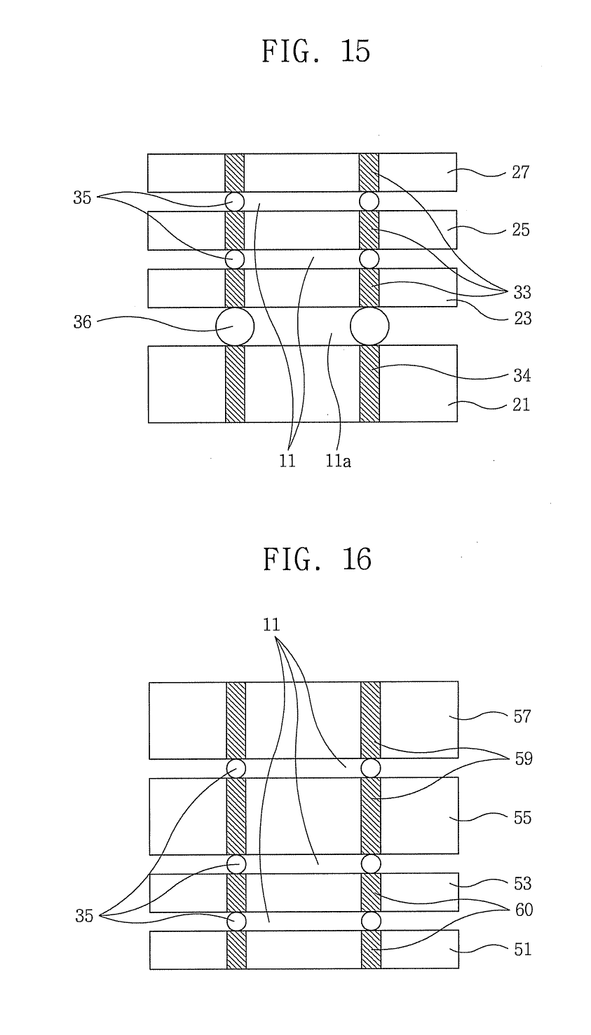

FIG. 17 is a plan view illustrating a semiconductor module including stacked semiconductor devices according to embodiments of the inventive concept.

Referring to FIG. 17, a semiconductor module employing stacked semiconductor devices according to example embodiments of the inventive concepts may include a module substrate 210, a plurality of semiconductor chips 207, and a control chip package 203. Input/output terminals 205 may be formed on the module substrate 210. The semiconductor chips 207 may have similar configurations to those described above. For example, the module substrate 210 may have a similar function to the main substrate 13 of FIG. 3.

The semiconductor chips 207 and the control chip package 203 may be mounted on the module substrate 210. The semiconductor chips 207 and the control chip package 203 may be electrically connected to the input/output terminals 205 in series or in parallel.

The control chip package 203 may be omitted. The semiconductor chips 207 may include a volatile memory chip (for example, a DRAM or an SRAM), a non-volatile memory chip (for example, a flash memory), a phase change memory, an MRAM or an RRAM, or a combination thereof.

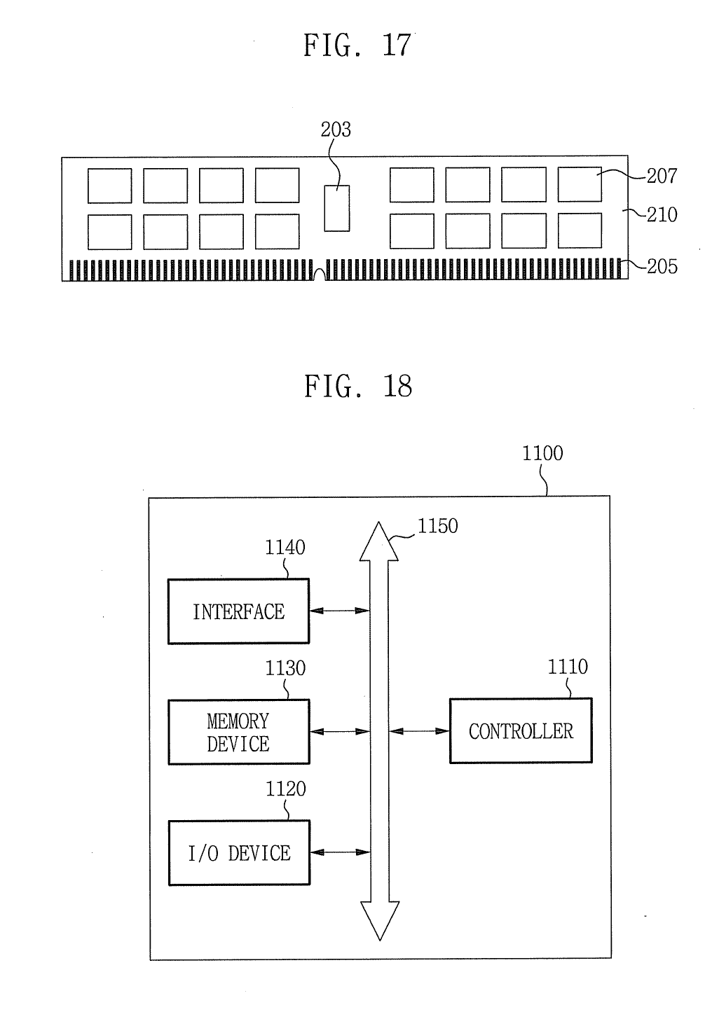

FIG. 18 is a block diagram illustrating an example of an electronic system including a stacked semiconductor device in accordance with example embodiments of the inventive concepts.

Referring to FIG. 18, an electronic system 1100 according to example embodiments of the inventive concepts may include a controller 1110, an input/output device 1120, a memory device 1130, an interface 1140, and a bus 1150. The memory device 1130 may include a stacked semiconductor device according to example embodiments of the inventive concepts. The bus 1150 may provide a path transferring data between the controller 1110, the input/output device 1120, the memory device 1130, and the interface 1140.

The controller 1110 may include at least one microprocessor, a digital signal processor, a microcontroller, and at least one of logic devices performing similar functions thereto. The input/output device 1120 may include at least one selected from a keypad, a keyboard, and a display device. The memory device 1130 may serve to store data and/or a command executed by the controller 1110.

The memory device 1130 may include a volatile memory chip (for example, a DRAM or a SRAM), a non-volatile memory chip (for example, a flash memory), a phase change memory, an MRAM or an RRAM, or a combination thereof. For example, the electronic system 1100 may be a solid-state disk (SSD).

The interface 1140 may serve to send data to a communication network or receive data from a communication network. The interface 1140 may be a wired/wireless type. For example, the interface 1140 may include an antenna or a wired/wireless transceiver. An application chipset, a camera image processor (CIS), and an input/output device may be further provided to the electronic system 1100.

The electronic system 1100 may be realized as a mobile system, a personal computer, an industrial computer, or a logic system performing various functions. For example, the mobile system may be one of a personal digital assistant (PDA), a web tablet, a mobile phone, a wireless phone, a laptop computer, a memory card, a digital music system, and a data transceiver system. When the electronic system 1100 is a device capable of performing wireless communication, the electronic system 1100 may be used for a communication system, for example, a code division multiple access (CDMA), a global system for mobile communication (GSM), North American digital cellular (NADC), enhanced-time division multiple access (E-TDMA), wideband code division multiple access (WCDAM), or CDMA2000.

The foregoing is illustrative of example embodiments and is not to be construed as limiting thereof. Although example embodiments have been described, those skilled in the art will readily appreciate that many modifications are possible in example embodiments without materially departing from the novel teachings and advantages. Accordingly, all such modifications are intended to be included within the scope of the inventive concepts as defined in the claims. In the claims, means-plus-function clauses are intended to cover the structures described herein as performing the recited function, and not only structural equivalents but also equivalent structures. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims.

What is claimed is:

1. A stacked semiconductor device, comprising:
a first semiconductor chip including a plurality of first through silicon vias (TSVs); and
at least one second semiconductor chip below the first semiconductor chip, the at least one second semiconductor chip including a plurality of second TSVs, wherein the at least one second semiconductor chip is thinner than the first semiconductor chip.

2. The stacked semiconductor device of claim 1, wherein each of the first TSVs is between upper and lower surfaces of the first semiconductor chip.

3. The stacked semiconductor device of claim 1, wherein each of the first TSVs is between a lower surface of the first semiconductor chip and an internal portion of the first semiconductor chip.

4. The stacked semiconductor device of claim 1, further comprising:
a main substrate below the at least one second semiconductor chip, wherein a lowermost semiconductor chip of the at least one second semiconductor chip is electrically coupled to the main substrate through external connecting terminals.

5. The stacked semiconductor device of claim 4, wherein the external connecting terminals includes at least one of a conductive bump and a solder ball.

6. The stacked semiconductor device of claim 1, wherein a lowermost semiconductor chip of the at least one second semiconductor chip is electrically coupled to a processor chip.

7. The stacked semiconductor device of claim 1, wherein the first semiconductor chip and the at least one second semiconductor chip are the same kinds of semiconductor chips.

8. The stacked semiconductor device of claim 1, wherein the first semiconductor chip and the at least one second semiconductor chip are different kinds of semiconductor chips.

9. The stacked semiconductor device of claim 1, wherein a first distance between the first semiconductor chip and a semiconductor chip adjacent to the first semiconductor chip among the at least one second semiconductor chip is longer than a second distance between the second semiconductor chips.

10. The stacked semiconductor device of claim 9, wherein the first distance and the second distance are adjusted according to a size of a conductive bump.

11. The stacked semiconductor device of claim 1, further comprising:
internal connecting terminals on the first semiconductor chip, wherein the internal connecting terminals are aligned with the first TSVs.

12. The stacked semiconductor device of claim 11, wherein the internal connecting terminals include at least one of a conductive bump and a solder ball.

13. The stacked semiconductor device of claim 1, further comprising:
an encapsulant covering the first semiconductor chip and the at least one second semiconductor chip.

14. The stacked semiconductor device of claim 13, wherein the encapsulant covers sidewalls of the first semiconductor chip and the at least one second semiconductor chip, and one surface of the first semiconductor chip is not covered with the encapsulant.

15. The stacked semiconductor device of claim 1, further comprising:
an auxiliary substrate on one surface of the first semiconductor chip.

16. The stacked semiconductor device of claim 1, further comprising:
an auxiliary substrate above the first semiconductor chip; and
a main substrate below the at least one second semiconductor chip.

17. The stacked semiconductor device of claim 16, further comprising:
an encapsulant covering the first semiconductor chip and the at least one second semiconductor chip.

18. The stacked semiconductor device of claim 17, wherein the encapsulant surrounds the auxiliary substrate.

19. A method of fabricating a stacked semiconductor device, the method comprising:
preparing a first semiconductor chip including a plurality of first through silicon vias (TSVs); and
stacking at least one second semiconductor chip including a plurality of second TSVs above the first semiconductor chip, wherein the at least one second semiconductor chip is thinner than the first semiconductor chip.

20. The method of claim 19, further comprising:
covering the first semiconductor chip and the at least one second semiconductor chip with an encapsulant.

21. A stacked semiconductor device, comprising:
a first semiconductor chip including a first plurality of through silicon vias;
at least one second semiconductor chip below the first semiconductor chip, the at least one second semiconductor chip including a second plurality of through silicon vias;
a plurality of internal connecting terminals between the first semiconductor chip and the at least one second semiconductor chip electrically connecting the first and second pluralities of through silicon vias;
a main substrate below the at least one second semiconductor conductor chip; and
at least one connecting terminal between the at least one second semiconductor chip and the main substrate electrically connecting the at least one second semiconductor chip to the main substrate, wherein a thickness of the first semiconductor chip is thicker than a thickness of the at least one second semiconductor chip.

22. The stacked semiconductor device of claim 21, further comprising:
an auxiliary substrate above the first semiconductor chip.

23. The stacked semiconductor device of claim 21, wherein the first semiconductor chip is at least twice as thick as the at least one second semiconductor chip.
